(19) United States
(12) Patent Application Publication
(10) Pub. No.: US 2008/0254305 A1
(43) Pub. Date: Oct. 16, 2008

(54) ORGANIC EL DEVICE

(75) Inventors: Toshihiko Takeda, Kawasaki-shi (JP); Manabu Otsuka, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/930,863

(22) Filed: Oct. 31, 2007

(30) Foreign Application Priority Data
Nov. 17, 2006 (JP) 2006-311251

(51) Int. Cl. B32B 15/00

(52) U.S. Cl. 428/457

(57) ABSTRACT

An object of the present invention is to provide an organic EL device including an electron injection layer having the state which can be specified with a physical quantity that can be measured with a simple measuring unit. The organic EL device includes, as an electron injection layer, a co-deposited film using a product obtained by evaporating at least one of a metal and a metal compound under heat and a product obtained by evaporating an organic substance under heat as raw materials, wherein the electron injection layer has a strength ratio of a maximum value for a Raman signal strength in a range of (1,600±50) cm⁻¹ to a maximum value for the Raman signal strength in a range of (1,360±60) cm⁻¹ which ratio is 1.1 or more.

### BACKGROUND OF THE INVENTION

1. Field of the Invention

The present invention relates to an organic electroluminescence (EL) device having at least a light-emitting layer and an electron injection layer interposed between a pair of electrodes.

2. Description of the Related Art

An organic EL device has been attracting attention in recent years because of its potential to serve as an emissive type thin display device. The technical objects of the organic EL device include a reduction in voltage at which the device is driven and an improvement in efficiency. To attain the objects, Japanese Patent Application Laid-Open No. 2002-100482 proposes an organic EL device including an electron transport layer in which at least a part of alkali metal molecules is each dispersed in a cation state. The electron transport layer disclosed by Japanese Patent Application Laid-Open No. 2002-100482 is a co-deposited film of an electron transportable material (organic substance) and Na (alkali metal) . Japanese Patent Application Laid-Open No. 2002-100482 describes that Na is not subjected to any cationization treatment at the time of the deposition of the film, but most of Na molecules in the resultant film are in a cation state.

However, the prior art disclosed in Japanese Patent Application Laid-Open No. 2002-100482 described above has involved the following problem.

The characteristics of the organic EL device (such as the voltage at which the device is driven and efficiency) vary from lot to lot, and the variation affects the production yield of the device in some cases. In the background of the foregoing is the following phenomenon: the state of the electron transport layer cannot be easily measured in some cases, so that it is difficult to make quantitative determination as to whether a predetermined electron transport layer is formed.

### SUMMARY OF THE INVENTION

In view of the foregoing, an object of the present invention is to provide an organic EL device capable of solving the problem described above. That is, an object of the present invention is to provide an organic EL device having an electron injection layer having the state which can be specified with a physical quantity that can be measured with a simple measuring unit.

According to the present invention, there is provided an organic EL device including, as an electron injection layer, a co-deposited film using a product obtained by evaporating at least one of a metal and a metal compound under heat and a product obtained by evaporating an organic substance under heat as raw materials, wherein the electron injection layer has a strength ratio of a maximum value for a Raman signal strength in a range of (1,600±50) cm⁻¹ to a maximum value for the Raman signal strength in a range of (1,360±60) cm⁻¹ which ratio is 1.1 or more.

According to the present invention, the state of the electron injection layer can be managed with a measured quantity that can be obtained with a simple measuring unit. Further, the state of the electron injection layer immediately after the formation of the layer in a vacuum chamber can also be measured. As a result, the occurrence of a defective item originating from the electron injection layer can be rapidly detected, and the production yield of the organic EL device can be increased.

Further features of the present invention will become apparent from the following description of exemplary embodiments with reference to the attached drawings.

### BRIEF DESCRIPTION OF THE DRAWINGS

FIG. 1 is a schematic view illustrating the constitution of an organic EL device of the present invention.

FIG. 2 is a graphical representation of a Raman spectrum.

FIG. 3 is a graphical representation of an optical absorption spectrum.

FIG. 4 is a schematic view illustrating a method of forming an electron injection layer according to the present invention.

FIG. 5 is a schematic view illustrating an example of a spectral measuring system.

FIG. 6 is a schematic view illustrating another example of a spectral measuring system.

FIG. 7 is a graphical representation illustrating an example of a Raman spectrum.

FIG. 8 is a graphical representation illustrating an example of an optical absorption spectrum.

### DESCRIPTION OF THE EMBODIMENTS

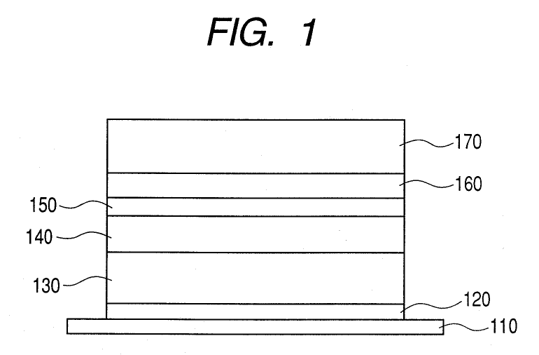

FIG. 1 shows an example of the constitution of an organic EL device according to the present invention (which may hereinafter be simply referred to as “device”). As shown in FIG. 1, the device includes a substrate 110, an anode 120, a hole transport layer 130, a light-emitting layer 140, an electron transport layer 150, an electron injection layer 160, and a cathode 170. A sealing structure for preventing the infiltration of, for example, moisture from the surroundings of the device is omitted in FIG. 1.

The electron injection layer 160 has Raman responsiveness and light-absorbing property to be described later.

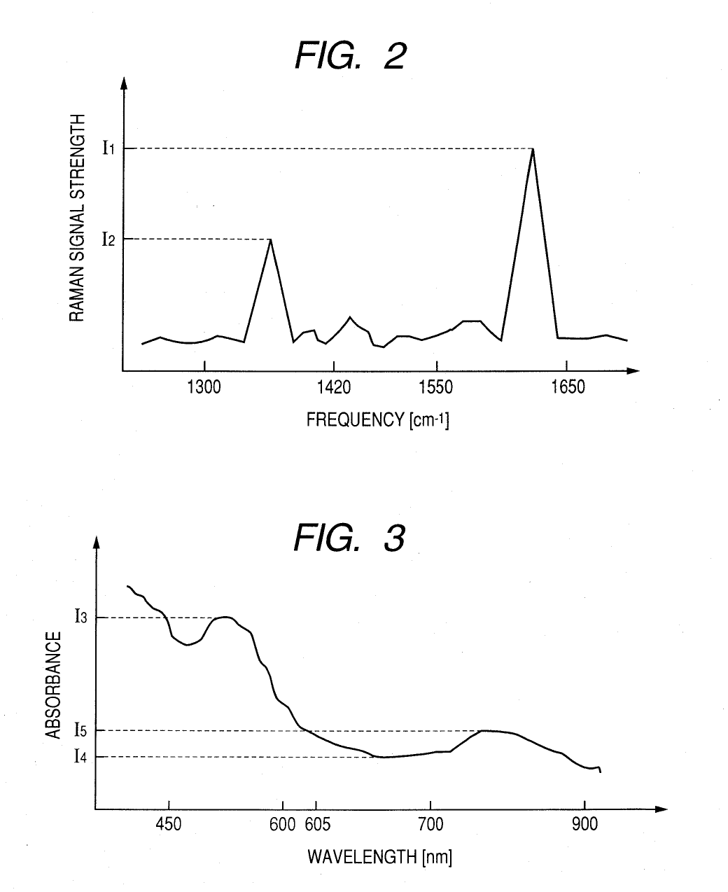

First, the Raman responsiveness will be described. The electron injection layer 160 is examined for Raman responsiveness by measuring the Raman scattered light of laser applied to the electron injection layer. FIG. 2 shows a graphical representation of a Raman spectrum obtained by the measurement. The axis of abscissa of FIG. 2 indicates a frequency, and the axis of ordinate of FIG. 2 indicates a Raman signal strength. In the present invention, attention is paid to a maximum value I₁ for the Raman signal strength in the range of (1,600±50) cm⁻¹ (see FIG. 2) and a maximum value I₂ for the Raman signal strength in the range of (1,360±60) cm⁻¹ (see FIG. 2). In the present invention, the electron injection layer 160 having a ratio (I₁/I₂) of the Raman signal strength I₁ to the Raman signal strength I₂ which ratio is 1.1 or more is used in the organic EL device.

The reason why attention was paid to the signals in the frequency ranges is as described below. The inactivation of an alkali metal or the like in the electron injection layer 160 with moisture or the like reduces the magnitude of the signal strength I₁. In addition, the magnitude of the signal strength I₁ depends on the concentration of the alkali metal in the electron injection layer 160. Attention is paid to the signal strength I₁ because the strength varies in synchronization with the state or concentration of the alkali metal or the like which affects the physical properties of the electron injection layer 160 as described above.

It should be noted that the Raman signal in the range of (1,600±50) cm⁻¹ is considered to result from a carbon crystalline structure present in the electron injection layer 160. On the other hand, the Raman signal in the range of (1,360±60) cm⁻¹ is considered to contain a component derived from a structure with low crystallinity present in the electron injection layer 160. The charge mobility of a crystalline structure is expected to be larger than that of a structure having a defect. Therefore, the above Raman signal strength ratio is considered to be a quantity related to the crystallinity and charge mobility of the electron injection layer 160.

Next, the light-absorbing property will be described. The electron injection layer 160 is examined for light-absorbing property by measuring its optical absorption spectrum. FIG. 3 shows a graphical representation of the optical absorption spectrum obtained by the measurement. The axis of abscissa of FIG. 3 indicates a wavelength, and the axis of ordinate of FIG. 3 indicates an absorbance.

In the present invention, attention is paid to a local maximum value I₃ for the absorbance in the wavelength range of 450 nm to 600 nm (see FIG. 3) and a local minimum value I₄ for the absorbance in the wavelength range of 605 nm to 700 nm (see FIG. 3). In the present invention, the electron injection layer 160 having a ratio (I₃/I₄) of the absorbance strength I₃ to the absorbance strength I₄ which ratio is 1.2 or more is used in the organic EL device. In addition, in the present invention, attention is paid also to a local maximum value I₅ for the absorbance in the wavelength range of 700 nm to 900 nm (see FIG. 3), and the electron injection layer 160 having a ratio (I₃/I₅) of the absorbance strength I₃ to the absorbance strength I₅ which ratio is 1.2 or more is used in the organic EL device.

The reason why attention was paid to the signals in the wavelength ranges is as described below. The inactivation of an alkali metal or the like in the electron injection layer 160 with moisture or the like reduces the magnitude of the signal strength I₃. In addition, the magnitude of the signal strength I₃ depends on the concentration of the alkali metal in the electron injection layer 160. Similarly, the magnitude of the signal strength I₅ also tends to depend on the concentration of the alkali metal in the electron injection layer 160. Attention is paid to the signal strength I₃ and any other signal strength because the strengths each vary in synchronization with the state or concentration of the alkali metal or the like which affects the physical properties of the electron injection layer 160 as described above. It should be noted that the occurrence of optical absorption in the range of 450 nm to 600 nm is considered to suggest the formation of a charge-transfer complex in the electron injection layer 160. In addition, optical absorption in the range of 700 nm to 900 nm is considered to suggest that the vibration of an organic substance which constitutes the electron injection layer 160 is formed be affected by the alkali metal or the like.

As described above, the electron injection layer 160 according to the present invention is specified with physical quantities such as Raman responsiveness and light-absorbing property that can be measured with a spectral measuring unit capable of performing the measurement simply as compared to a measuring unit using an X-ray or the like. As a result, whether the electron injection layer 160 during a production process or after the production of the organic EL device is good or bad can be determined, and the production yield of the organic EL device can be increased.

The organic EL device having a constitution schematically shown in FIG. 1 can be formed by sequentially stacking, on the substrate 110, the anode 120, the hole transport layer 130, the light-emitting layer 140, the electron transport layer 150, the electron injection layer 160, and the cathode 170 by a known method (such as a vacuum deposition method).

The electron injection layer 160 according to the present invention is a co-deposited film using a product obtained by evaporating at least one of a metal and a metal compound under heat and a product obtained by evaporating an organic substance under heat as raw materials.

Examples of the metal include alkali metals (such as Li, Na, K, Rb, and Cs) and/or alkaline earth metals (such as Mg, Ca, Sr, and Ba). Examples of the metal compound include alkali metal compounds and/or alkaline earth metal compounds. Examples of the alkali metal compounds include the oxides, carbonates, chlorides, fluorides, and sulfides of the alkali metals. Examples of the above alkaline earth metal compounds include the oxides, carbonates, chlorides, fluorides, and sulfides of the alkaline earth metals.

An organic substance having an electron transport property and capable of being formed into a deposited film by a vacuum heating treatment can be used as a raw material for the electron injection layer 160. For example, a known aluminum quinolinol complex or phenanthroline compound can be used.

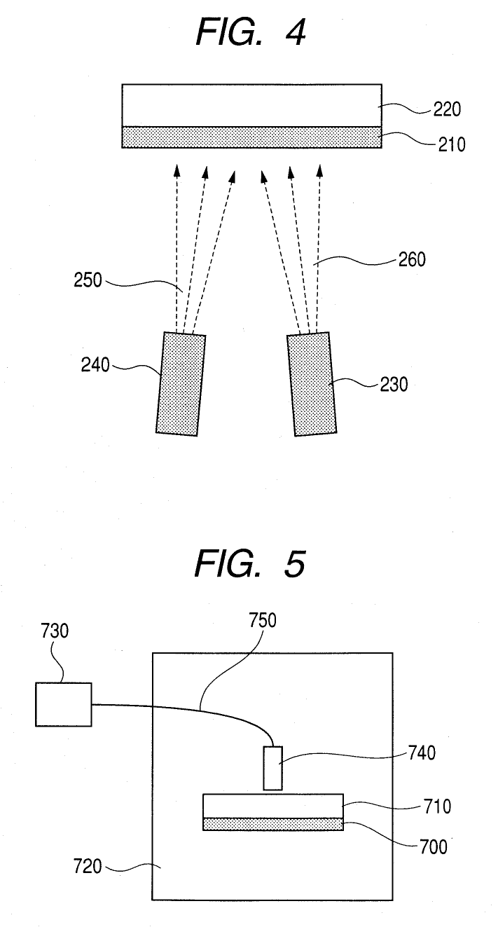

FIG. 4 is a schematic view illustrating the step of forming an electron injection layer according to the present invention. In FIG. 4, an electron injection layer 210 is formed on a substrate 220. As described above, the electron injection layer 210 is a co-deposited film of raw materials roughly classified into two kinds. A first raw material is a product obtained by evaporating an organic substance under heat. A second raw material is a product obtained by evaporating at least one kind of a substance selected from an alkali metal, an alkali metal compound, an alkaline earth metal, and an alkaline earth metal compound under heat. In FIG. 4, there is arranged a deposition source 230 for producing the product obtained by evaporating an organic substance under heat. Also, there is arranged a deposition source 240 for producing the product obtained by evaporating at least one kind of a substance selected from the alkali metal, the alkali metal compound, the alkaline earth metal, and the alkaline earth metal compound under heat. The product 260 obtained by evaporating an organic substance under heat travels from the deposition source 230 toward the substrate 220. The product 250 obtained by evaporating at least one kind of a substance selected from an alkali metal, an alkali metal compound, an alkaline earth metal, and an alkaline earth metal compound under heat travels from the deposition source 240 toward the substrate 220.

A degree of vacuum in a vacuum chamber at the time of the initiation of the formation of the electron injection layer 210 according to the present invention is preferably higher than 9×10⁻⁵ Pa. Alternatively, only an alkali metal is preferably evaporated before the formation of the electron injection layer 210. This is because the inactivation of an alkali metal vapor in the vacuum chamber with moisture or the like should be prevented at the time of the formation of the electron injection layer 210. The amount of oxygen or moisture in the chamber can be reduced by increasing the degree of vacuum in the vacuum chamber. In addition, when the alkali metal is evaporated in advance, moisture in the vacuum chamber reacts with the alkali metal vapor to be consumed.

In the present invention, whether the predetermined electron injection layer 210 is formed is confirmed by the above spectral measurement. The spectral measurement may be performed during a formation process or immediately after the formation of the electron injection layer 210, or may be performed after the production of the organic EL device. Alternatively, the following procedure may be adopted: a region where only the electron injection layer 210 is formed is provided around the organic EL device, and the region is subjected to the spectral measurement.

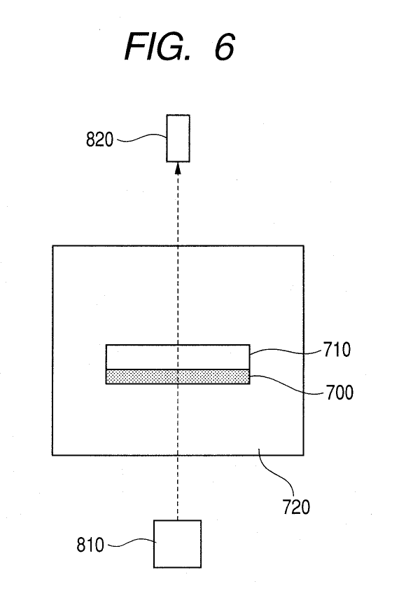

FIGS. 5 and 6 each show an example of a method for spectral measurement for the electron injection layer 210 immediately after the formation of the electron injection layer 210. FIG. 5 is a schematic view of a Raman measuring system. FIG. 6 is a schematic view of an absorbance measuring system.

In FIG. 5, an electron injection layer 700 or the above-mentioned co-deposited film 700 in a spectral measurement region is formed on a substrate portion 710 for supporting the layer. The system of FIG. 5 includes a Raman spectrometer main body 730 placed outside a vacuum chamber 720, and a probe head 740 connected to the Raman spectrometer main body with an optical fiber 750. Laser light is applied to a sample through the optical fiber 750. Raman scattered light from the sample is collected with the probe 740, and is sent to the Raman spectrometer main body through the optical fiber 750. Raman measurement for the electron injection layer 700 in the vacuum chamber 720 may be performed with the system described above.

The system in FIG. 6 includes a light source 810 for absorbance measurement and an absorbance meter 820. The light source and the optical sensor are placed outside the vacuum chamber 720. It should be noted that the vacuum chamber 720 is provided with a window through which light from the light source 810 can be incident upon the inside of the vacuum chamber 720. Similarly, the chamber is provided with a window through which transmitted light for measurement can be incident upon the absorbance meter. Absorbance measurement for the electron injection layer 700 in the vacuum chamber 720 may be performed with the system described above.

Hereinafter, the present invention will be described by way of examples.

### EXAMPLES 1

In this example, an organic EL device having a constitution as shown in FIG. 1 is produced.

The anode 120 formed of chromium (thickness: 200 nm) is formed on the substrate 110 by a sputtering method. The anode 120 has a light-reflecting function.

Next, the substrate on which the anode 120 has been formed is subjected to a UV/ozone cleaning treatment. Subsequently, the cleaned substrate and a material for deposition are placed in a chamber of a vacuum deposition apparatus, and the inside of the chamber is evacuated to 1.3×10⁻⁴ Pa. After a predetermined degree of vacuum has been achieved, the hole transport layer 130 (thickness: 60 nm) is formed on the anode 120. A material for the hole transport layer 130 is N,N′-α-dinaphthylbenzidine (α-NPD).

The light-emitting layer 140 (thickness: 30 nm) is formed on the hole transport layer 130. The light-emitting layer 140 is a co-deposited film of coumarin 6 (1.0 wt %) and tris[8-hydroxyquinolinato]aluminum (Alq3).

The electron transport layer 150 (thickness: 10 nm) is formed on the light-emitting layer 140. A material for the electron transport layer 150 is a phenanthroline compound.

Next, the inside of the chamber is evacuated to 8.5×10⁻⁵ Pa. After that, the electron injection layer 160 (thickness: 40 nm) is formed on the electron transport layer 150. The electron injection layer 160 of this example is a co-deposited film using a product obtained by evaporating a phenanthroline compound under heat and a product obtained by evaporating metal cesium under heat as raw materials. It should be noted that a cesium concentration in the electron injection layer 160 is about 2 wt %. At the time of the formation of the electron injection layer 160, a co-deposited film corresponding to the electron injection layer 160 is formed in a region except a region where the organic EL device is to be formed. The co-deposited film formed in the region is in the same state as that of the electron injection layer 160 of the organic EL device. The co-deposited film in the region is used as a region for spectral measurement to be described later.

The cathode 170 through which light from the light-emitting layer 140 can be extracted (thickness: 150 nm) is formed on the electron injection layer 160 by a sputtering method. A material for the cathode 170 is an indium tin oxide (ITO). It should be noted that the ITO is not formed on the region for spectral measurement.

After that, the substrate is transferred to a glove box, and is sealed with a glass cap (not shown) containing a desiccant in a nitrogen atmosphere.

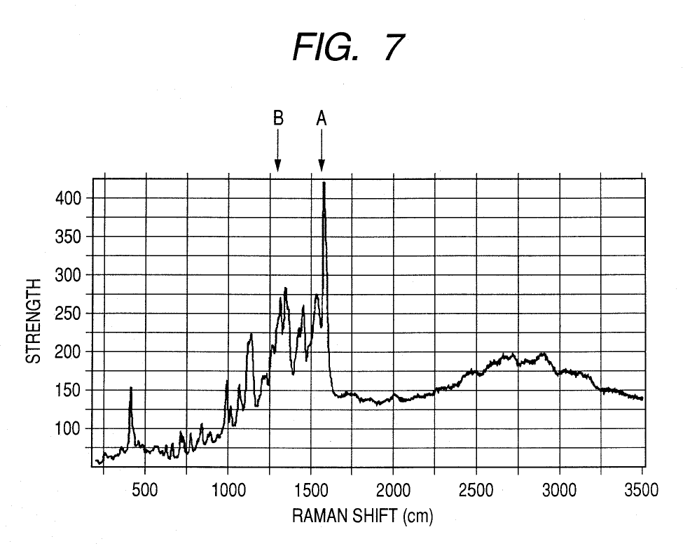

Next, the region for spectral measurement is subjected to Raman measurement. FIG. 7 shows the result of the Raman measurement. A signal indicated by a symbol A in FIG. 7 is a signal showing the maximum strength in the range of (1,600±50) cm⁻¹ (referred to as “I₁”). On the other hand, a signal indicated by a symbol B in FIG. 7 is a signal showing the maximum strength in the range of (1,360±60) cm⁻¹ (referred to as “I₂”). A strength ratio between those signals (I₁/I₂) is 1.5.

The organic EL device produced by the above procedure is examined for light-emitting characteristic by applying a DC voltage to the device. As a result, the device shows a current density of 70.5 mA/cm² when a voltage of 5.8 V is applied, and shows a luminous efficiency of 4 cd/A when a voltage of 5.8 V is applied.

### EXAMPLE 2

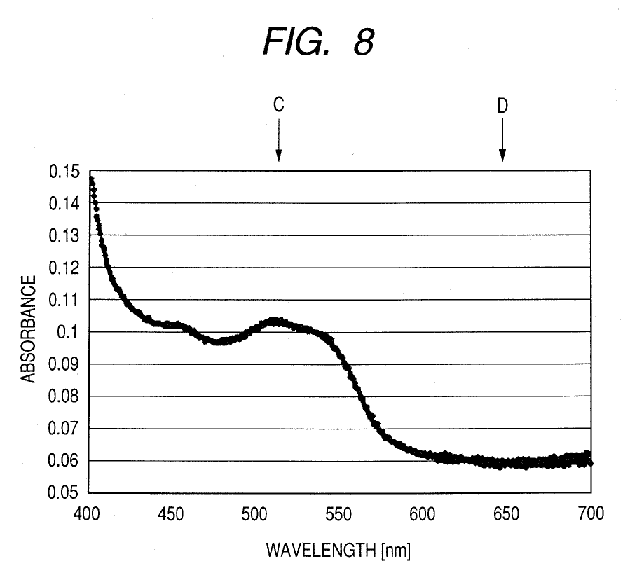

In this example, the region for spectral measurement of Example 1 is subjected to absorbance measurement. FIG. 8 shows the obtained result of the absorbance measurement. A signal indicated by a symbol C in FIG. 8 is a signal showing the maximum strength in the wavelength range of 450 nm to 600 nm (referred to as “I₃”) On the other hand, a signal indicated by a symbol D in FIG. 8 is a signal showing the minimum strength in the wavelength range of 605 nm to 700 nm (referred to as “I₄”) . A strength ratio between those signals (I₃/I₄) is 1.8. In addition, a strength ratio (I₃/I₅) of the signal I₃ to the local maximum value I₅ for the absorbance in the wavelength range of 700 nm to 900 nm is 1.5.

### COMPARATIVE EXAMPLE 1

In this comparative example, an organic EL device is produced in the same manner as in Example 1 except that the inside of the vacuum chamber immediately before the formation of the electron injection layer is evacuated to have a degree of vacuum of 3.5×10⁻³ Pa.

The region for spectral measurement is subjected to Raman measurement and absorbance measurement in the same manner as in Example 1. The magnitude of the signal strength ratio (I₁/I₂) described in Example 1 is 0.8. The signal strength ratio (I₃/I₄) described in Example 1 is 0.7.

The characteristics of the resultant organic EL device are measured. As a result, the device shows a current density of 43.2 mA/cm² when a voltage of 5.8 V is applied, and shows a luminous efficiency of 3.0 cd/A when a voltage of 5.8 V is applied.

### EXAMPLE 3

In this example, an organic EL device is produced in the same manner as in Example 1 except that the evaporation of only metal cesium under heat is continued for 30 minutes after the degree of vacuum in the vacuum chamber after the formation of the electron transport layer has reached 1.3×10⁻³ Pa.

A region for spectral measurement is formed also in this example in the same manner as in Example 1. The region for spectral measurement is subjected to Raman measurement. A ratio (I₁/I₂) of the maximum signal strength (I₁) in the range of (1,600±50) cm⁻¹ to the maximum signal strength (I₂) in the range of (1,360±60) cm⁻¹ is 1.5. The region for spectral measurement is subjected to absorbance measurement. A ratio (I₃/I₄) of the maximum signal strength (I₃) in the wavelength range of 450 nm to 600 nm to the minimum signal strength (I₄) in the wavelength range of 605 nm to 700 nm is 1.8.

The organic EL device produced by the above procedure is examined for light-emitting characteristic by applying a DC voltage to the device. As a result, the device shows a current density of 70.5 mA/cm² when a voltage of 5.8 V is applied, and shows a luminous efficiency of 4 cd/A when a voltage of 5.8 V is applied.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2006-311251, filed Nov. 17, 2006, which is hereby incorporated by reference herein in its entirety.

What is claimed is:

1. An organic EL device comprising, as an electron injection layer, a co-deposited film using a product obtained by evaporating at least one of a metal and a metal compound under heat and a product obtained by evaporating an organic substance under heat as raw materials, wherein the electron injection layer has a strength ratio of a maximum value for a Raman signal strength in a range of (1,600±50) cm⁻¹ to a maximum value for the Raman signal strength in a range of (1,360±60) cm⁻¹ which ratio is 1.1 or more.

2. An organic EL device according to claim 1, wherein the electron injection layer has a strength ratio of a local maximum value for an absorbance in a wavelength range of 450 nm to 600 nm to a local minimum value for the absorbance in a wavelength range of 605 nm to 700 nm which ratio is 1.2 or more.

3. An organic EL device according to claim 1, wherein the electron injection layer has a strength ratio of a local maximum value for an absorbance in a wavelength range of 700 nm to 900 nm to a local maximum value for the absorbance in a wavelength range of 450 nm to 600 nm which ratio is 1.2 or more.

4. An organic EL device according to claim 1, wherein the metal is at least one of an alkali metal and an alkaline earth metal.

5. An organic EL device according to claim 1, wherein the metal compound is at least one of an alkali metal compound and an alkaline earth metal compound.
